(19) United States
(12) Patent Application Publication
(10) Pub. No.: US 2015/0214167 A1
(43) Pub. Date: Jul. 30, 2015

(54) SEMICONDUCTOR DIE WITH VARIABLE LENGTH BOND PAD

(71) Applicants: Rishi Bhooshan, Ghaziabad (IN); Sachin Kalra, Ghaziabad (IN); Rakesh Pandey, Ghaziabad (IN); Dzung T. Tran, Austin, TX (US)

(72) Inventors: Rishi Bhooshan, Ghaziabad (IN); Sachin Kalra, Ghaziabad (IN); Rakesh Pandey, Ghaziabad (IN); Dzung T. Tran, Austin, TX (US)

(21) Appl. No.: 14/164,249

(22) Filed: Jan. 26, 2014

(51) Int. Cl. H01L 23/00

(52) U.S. Cl. CPC H01L 24/06; H01L 24/49; H01L 2224/04042; H01L 2224/06151; H01L 2224/05013; H01L 2224/48091; H01L 2224/48101; H01L 2224/48157; H01L 2224/49175

(57) ABSTRACT

A semiconductor die has elongate, adjacent external interface cells that form an interface cell row. Each of the external interface cells provides an external interface for a circuit node of the die. Bond pads are disposed on a surface of the die, with each of the bond pads being electrically connected to a directly underlying one of the interface cells of the interface cell row. Each of the bond pads has a longitudinal axis aligned with a lengthwise axis of its respective directly underlying interface cell. Each of the bond pads also has a multiple potential wire bond site locations along its respective longitudinal axes.

### BACKGROUND OF THE INVENTION

The present invention relates generally to semiconductor integrated circuits and, more particularly, to a semiconductor die with a variable length bond pad cell.

Semiconductor die packages are typically formed with a semiconductor die mounted on a lead frame die flag (die pad). External connectors in the form of leads of the lead frame are electrically coupled, by bond wires, to die bond pads on the die. After the connectors and bond pads are coupled by the bond wires, the semiconductor die and connectors are encapsulated (packaged) in a compound such as a plastics material leaving sections of the external connectors (leads) exposed. The mold compound forms a package body and the end regions of the leads either project outwardly from the package body or are at least flush with the package body so they can be used as terminals, allowing the semiconductor package to be electrically connected directly to other devices or to a printed circuit board (PCB).

Semiconductor die packages are often being manufactured with increased functionality and this results in an increase in the number of required bond pads. This increase in the number of required bond pads may necessitate an increased footprint size of the die, and overall package size, in order to comply with packaging rules such as: maximum and minimum allowable bond wire height; minimum bond site spacing; and maximum bend angle of a bond wire. Thus, it would be advantageous to be able to either accommodate more bond pads on a surface of the die provide bond pads that can accommodate multiple bond wires connections thereto.

### BRIEF DESCRIPTION OF THE DRAWINGS

The invention, together with objects and advantages thereof, may best be understood by reference to the following description of preferred embodiments together with the accompanying drawings in which:

FIG. 1 is a partial plan view of a conventional semiconductor die package;

FIG. 2 is a partial plan view of a semiconductor die package according to a first embodiment of the present invention;

FIG. 3 is a partial plan view of a semiconductor die package according to a second embodiment of the present invention;

FIG. 4 is a partial plan view of a semiconductor die package according to a third embodiment of the present invention;

FIG. 5 is a partial plan view of a semiconductor die package according to a fourth embodiment of the present invention; and

FIG. 6 is a partial plan view of a semiconductor die package according to a fifth embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one aspect of the present invention, a semiconductor die having elongate adjacent external interface cells forming an interface cell row is provided. Each of the external interface cells provides an external interface for a circuit node of the die. Die bond pads are formed on the surface of the die, with each one being electrically connected to a directly underlying interface cell of the interface cell row. Each of the bond pads has a longitudinal axis aligned with a lengthwise axis of the respective directly underlying interface cell. Each of the bond pads also has a plurality of potential wire bond site locations along its respective longitudinal axe.

In another aspect of the present invention, a semiconductor die package having external connector wire bond locations associated with respective external connectors of the package is provided. A semiconductor die that has respective edges proximal to the external wire bond locations includes a plurality of elongate adjacent external interface cells forming an interface cell row. Each of the external interface cells provides an external interface for a circuit node of the die. Bond pads are formed on an active surface of the die. Each of the bond pads is electrically connected to a directly underlying interface cell of the interface cell row. Each of the bond pads has a longitudinal axis aligned with a lengthwise axis of the respective directly underlying interface cell. Each of the bond pads also has a plurality of potential wire bond site locations along its longitudinal axis. Bond wires selectively electrically couple each of the bond pads to one of the external connector wire bond locations. At least two of the bond wires are bonded to a respective bond pad at different wire bond site locations along its longitudinal axis.

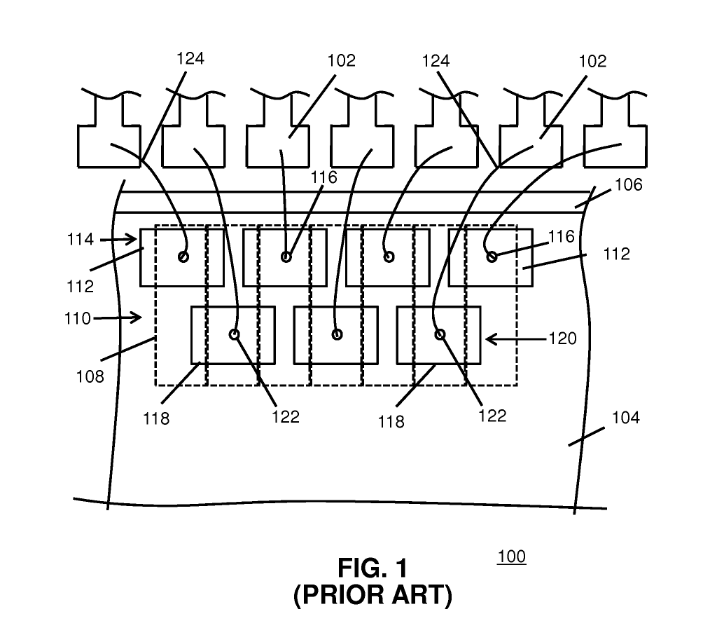

Referring now to FIG. 1, a partial plan view of a conventional semiconductor die package 100 is illustrated. The semiconductor die package 100 includes external connector wire bond locations 102, associated with respective external connectors of the package 100, and a semiconductor die 104 that in this embodiment is mounted on a die flag 106. The external connector wire bond locations 102 are bond sites at the end of lead fingers. The semiconductor die 104 includes a plurality of elongate adjacent external interface cells 108 (indicated in phantom) forming an interface cell row 110. As is known in the art, each of the external interface cells 108 provides an external interface for a circuit node of the semiconductor die 104.

The semiconductor die 104 includes a plurality of first row bond pads 112 that form a first row of spaced second bond pads 114. Each of the first row bond pads 112 is electrically connected to a directly underlying interface cell 108 of the interface cell row 110. The first row bond pads 112 also each have a single bond site location 116 (indicated by a circle).

A second row bond pads 118 is provided that form a second row of spaced second bond pads 120. Each of the second row bond pads 118 is electrically connected to a directly underlying interface cell 108 of the interface cell row 110. The second row bond pads 118 also each have a single bond site location 122 (indicated by a circle).

The semiconductor die package 100 also has bond wires 124 that are bonded (welded) to selectively electrically couple each of the bond pads 112, 118 to one of the external connector wire bond locations 102. This conventional semiconductor die package 100 may require increased footprint size of the die and overall package size in order to comply with packaging rules such as: maximum and minimum allowable bond wire loop height; minimum bond site spacing; and maximum bend angle of a bond wire because the first and second row bond pads 112, 118 are of a shape and size that only allows for bonding of the bond wires 124 to their respective single bond site locations 116, 122.

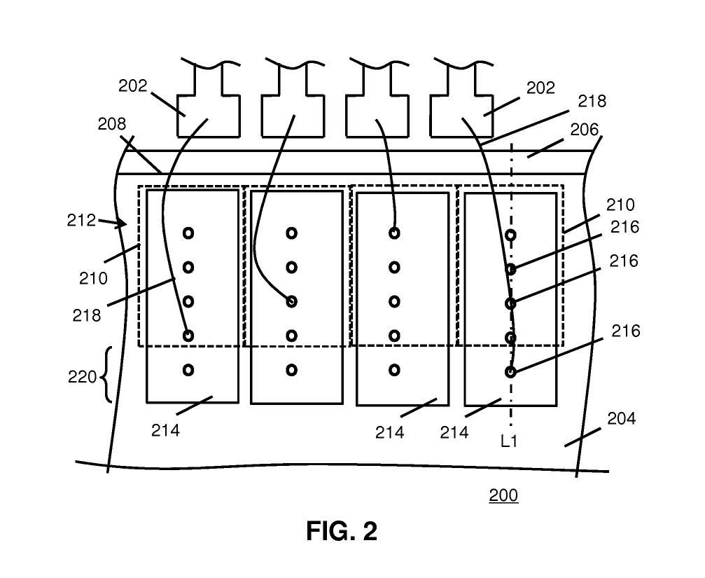

Referring now to FIG. 2, a partial plan view of a semiconductor die package 200 according to a first embodiment of the present invention is shown. The semiconductor die package 200 includes external connector wire bond locations 202 associated with respective external connectors of the package 200, and a semiconductor die 204 that in this embodiment is mounted on a die flag 206. In this embodiment, the external connector wire bond locations 202 are bond pads at the end of lead fingers as will be apparent to a person skilled in the art.

The semiconductor die 204 has respective edges, such as edge 208, proximal to the external connector wire bond locations 202. The semiconductor die 204 includes a plurality of elongate adjacent external interface cells 210 (indicated in phantom) forming an interface cell row 212. As will be apparent to a person skilled in the art, each of the external interface cells 210 provides an external interface for a circuit node of the semiconductor die 204.

The semiconductor die 204 also includes a plurality of bond pads 214, each of the bond pads 214 is electrically connected to a directly underlying interface cell 210 of the interface cell row 212, and each of the bond pads 214 has a longitudinal axis L1 aligned with a lengthwise axis of their respective directly underlying interface cell 210. Each of the bond pads 214 has a plurality of potential wire bond site locations 216 (indicated by circles) along their respective longitudinal axis L1. The semiconductor die package 200 also has bond wires 218 that are bonded (welded) to selectively electrically couple each of the bond pads 214 to one of the external connector wire bond locations 202. Further, at least two bond wires 218 are bonded to a respective adjacent bond pad 214 at different wire bond site locations 216 along their respective longitudinal axes L1.

Each of the bond pads 214 are rectangular and extend to a non-overlying region 220 of the interface cell row 212. As will be apparent to a person skilled in the art, an encapsulation material (not shown) typically encapsulates the semiconductor die 204, bond wires 218, die flag 206 and external connector wire bond locations 202.

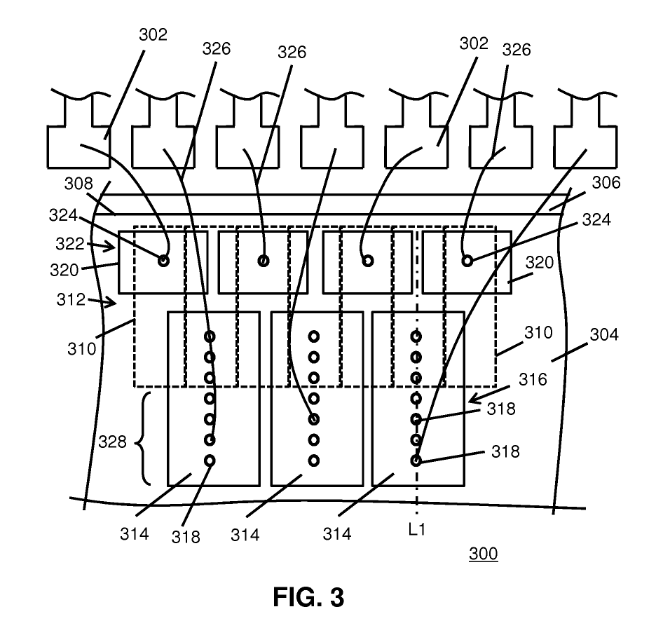

Referring to FIG. 3. a partial plan view of a semiconductor die package 300 according to a second embodiment of the present invention is shown. The semiconductor die package 300 includes external connector wire bond locations 302 associated with respective external connectors of the package 300, and a semiconductor die 304 that in this embodiment is mounted on a die flag 306. In this embodiment, the external connector wire bond locations 302 are bond pads at the end of lead fingers as will be apparent to a person skilled in the art.

The semiconductor die 304 has respective edges, such as edge 308, proximal to the external connector wire bond locations 302. The semiconductor die 304 includes a plurality of elongate adjacent external interface cells 310 (indicated in phantom) forming an interface cell row 312. As will be apparent to a person skilled in the art, each of the external interface cells 310 provides an external interface for a circuit node of the semiconductor die 304.

The semiconductor die 304 also includes a plurality of first row bond pads 314 that form a first row of spaced first bond pads 316. Each of the first row bond pads 314 is electrically connected to a directly underlying interface cell 310 of the interface cell row 312, and each of the first row bond pads 314 has a longitudinal axis L1 aligned with a lengthwise axis of their respective directly underlying interface cell 310. Each of the first row bond pads 314 has a plurality of potential wire bond site locations 318 (indicated by circles) along their respective longitudinal axes L1.

A plurality of second row bond pads 320 are provided that form a second row of spaced second bond pads 322. Each of the second row bond pads 320 is electrically connected to a directly underlying interface cell 310 of the interface cell row 312. In this embodiment, the second row bond pads 320 each have a single bond site location 324 (indicated by a circle).

The semiconductor die package 300 also has bond wires 326 that are bonded (welded) to selectively electrically couple each of the bond pads 314, 320 to one of the external connector wire bond locations 302. Further, at least two bond wires 326 are bonded to respective adjacent first row bond pads 314 at different wire bond site locations 318 along their respective longitudinal axes L1.

Each of the first row bond pads 314 are rectangular and extend to a non-overlying region 328 of the interface cell row 312. Each of the first row bond pads 314 also overlay two other adjacent circuit external interface cells 310 that sandwich the respective directly underlying interface cell 310. Similarly, each of the second row bond pads 320 overlay two adjacent circuit external interface cells 310 that sandwich the respective directly underlying interface cell 310. As will be apparent to a person skilled in the art, an encapsulation material (not shown) typically encapsulates the semiconductor die 304, bond wires 326, die flag 306 and external connector wire bond locations 302.

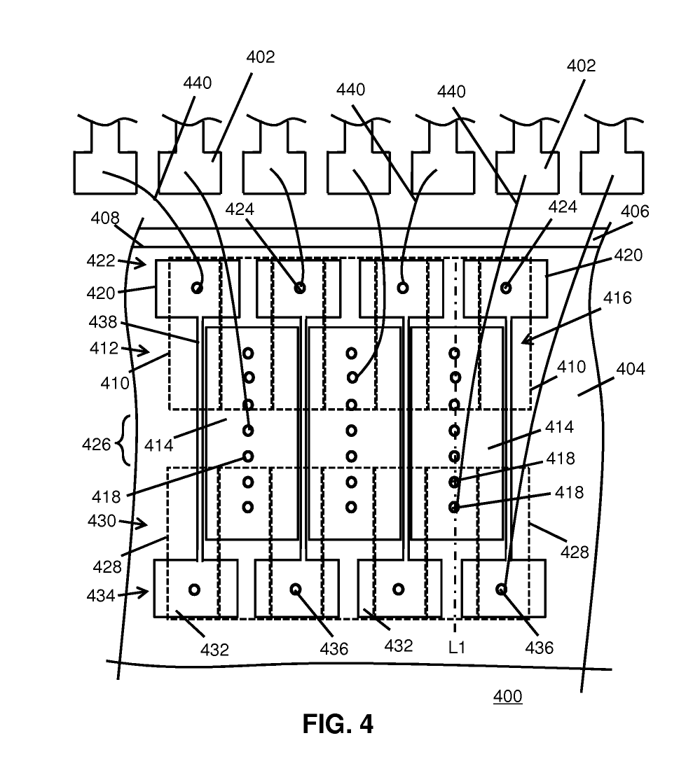

FIG. 4 is partial plan view of a semiconductor die package 400 according to a third embodiment of the present invention. The semiconductor die package 400 includes external connector wire bond locations 402 associated with respective external connectors of the package 400, and a semiconductor die 404 that in this embodiment is mounted on a die flag 406. In this embodiment, the external connector wire bond locations 402 are bond sites at the end of lead fingers as will be apparent to a person skilled in the art.

The semiconductor die 404 has respective edges, such as edge 408, proximal to the external connector wire bond locations 402. The semiconductor die 404 includes a plurality of elongate adjacent external interface cells 410 (indicated in phantom) forming an interface cell row 412. As will be apparent to a person skilled in the art, each of the external interface cells 410 provides an external interface for a circuit node of the semiconductor die 404.

The semiconductor die 404 also includes a plurality of first row bond pads 414 that form a first row of spaced first bond pads 416. Each of the first row bond pads 414 is electrically connected to a directly underlying interface cell 410 of the interface cell row 412. Each of the first row bond pads 414 has a longitudinal axis L1 aligned with a lengthwise axis of their respective directly underlying interface cell 410. Also, each of the first row bond pads 414 has a plurality of potential wire bond site locations 418 (indicated by circles) along their respective longitudinal axes L1.

There is also a plurality of second row bond pads 420 that form a second row of spaced second bond pads 422 and each of the second row bond pads 420 is electrically connected to a directly underlying interface cell 410 of the interface cell row 412. In this embodiment, the second row bond pads 420 each have a single bond site location 424 (indicated by a circle).

Each of the first row bond pads 414 are rectangular and extend to a non-overlying region 426 of the interface cell row 412. In this embodiment, the interface cell row 412 is an outer interface cell row proximal to the proximal edge 408 of the die 404, and the outer interface cell row is located between the proximal edge 408 and the non-overlying region 426. There is also a plurality of inner adjacent external interface cells 428 forming an inner interface cell row 430. Each of the inner external interface cells 428 provides an external interface for a circuit node of the die 404. The semiconductor die package 400 further includes a plurality of third row bond pads 432 that form a third row of spaced third bond pads 434 electrically connected to a directly underlying interface cell 428 of the inner interface cell row 430. In this embodiment, the third row bond pads 432 each have a single bond site location 436 (indicated by a circle).

The third row bond pads 432 are directly selectively electrically connected to one of the respective spaced second bond pads 420 by a respective runner 438. Also, each of the first row bond pads 414 extends to overlay a respective one of the external interface cells 428 of the inner interface cell row 430.

The semiconductor die package 400 also has bond wires 440 that are bonded (welded) to selectively electrically couple each of the bond pads 414, 420, 432 to one of the external connector wire bond locations 402. Further, at least two bond wires 440 are bonded to respective adjacent first row bond pads 414 at different wire bond site locations 418 along their respective longitudinal axes L1.

Also, each of the first row bond pads 416 overlay two other adjacent circuit external interface cells 410 that sandwich the respective directly underlying interface cell 410. Additionally, each of the second row bond pads 420 overlay two adjacent circuit external interface cells 410 that sandwich the respective directly underlying interface cell 410. Similarly, the third row bond pads 432 overlay two adjacent circuit external interface cells 428 that sandwich the respective directly underlying interface cell 428.

As will be apparent to a person skilled in the art, an encapsulation material (not shown) typically encapsulates the semiconductor die 404, bond wires 440, die flag 406 and external connector wire bond locations 402.

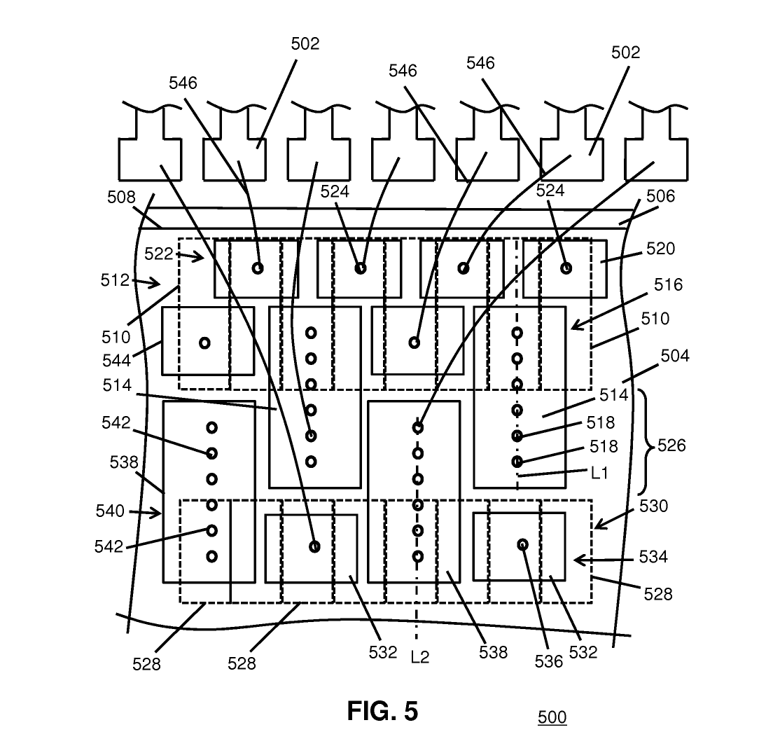

Referring now to FIG. 5, a partial plan view of a semiconductor die package 500 according to a fourth embodiment of the present invention is shown. The semiconductor die package 500 includes external connector wire bond locations 502 associated with respective external connectors of the package 500, and a semiconductor die 504 that in this embodiment is mounted on a die flag 506. In this embodiment, the external connector wire bond locations 502 are bond sites at the end of lead fingers as will be apparent to a person skilled in the art.

The semiconductor die 504 has respective edges, such as edge 508, proximal to the external connector wire bond locations 502. The semiconductor die 504 includes a plurality of elongate adjacent external interface cells 510 (indicated in phantom) forming an interface cell row 512. As will be apparent to a person skilled in the art, each of the external interface cells 510 provides an external interface for a circuit node of the semiconductor die 504.

The semiconductor die 504 also includes a plurality of first row bond pads 514 that form a first row of spaced first bond pads 516. Each of the first row bond pads 514 is electrically connected to a directly underlying interface cell 510 of the interface cell row 512. Each of the first row bond pads 514 has a longitudinal axis L1 aligned with a lengthwise axis of their respective directly underlying interface cell 510. Also, each of the first row bond pads 514 has a plurality of potential wire bond site locations 518 (indicated by circles) along their respective longitudinal axes L1.

There is also a plurality of second row bond pads 520 that form a second row of spaced second bond pads 522 and each of the second row bond pads 520 is electrically connected to a directly underlying interface cell 510 of the interface cell row 512. In this embodiment, the second row bond pads 520 each have a single bond site location 524 (indicated by a circle).

Each of the first row bond pads 514 are rectangular and extend to a non-overlying region 526 of the interface cell row 512. In this embodiment, the interface cell row 512 is an outer interface cell row proximal to the proximal edge 508 of the die 504, and the outer interface cell row is located between the proximal edge 508 and the non-overlying region 526. There is also a plurality of inner adjacent external interface cells 528 forming an inner interface cell row 530. Each of the inner external interface cells 528 provides an external interface for a circuit node of the die 504. The semiconductor die package 500 further includes a plurality of third row bond pads 532 that form a third row of spaced third bond pads 534 electrically connected to a directly underlying interface cell 528 of the inner interface cell row 530. In this embodiment, the third row bond pads 532 each have a single bond site location 536 (indicated by a circle).

The semiconductor die 504 also has a plurality of fourth row bond pads 538 forming a fourth row of spaced fourth bond pads 540 that are electrically connected to a directly underlying interface cell 528 of the inner interface cell row 530. The fourth row bond pads 538 have a longitudinal axis L2 aligned with a lengthwise axis of their respective said overlaid interface cell 528. Each of the fourth row bond pads 538 have a plurality of potential wire bond site locations 542 along their respective longitudinal axes L2. Further, each of the fourth row bond pads 538 are rectangular and extend to the non-overlying region 526 such that the first and fourth row bond pads 514, 538 are interleaved in the non-overlying region 526. There are also further bond pads 544 sandwiched between the first row bond pads 514, these further bond pads 544 are also electrically connected to a directly underlying interface cell 510 of the interface cell row 512.

The semiconductor die package 500 also has bond wires 546 that are bonded (welded) to selectively electrically couple each of the bond pads 514, 520, 532, 538, 544 to one of the external connector wire bond locations 502. Further, at least two bond wires 546 are bonded to respective adjacent first row bond pads 514 at different wire bond site locations 518 along their respective longitudinal axes L1. Similarly, at least two bond wires 546 are bonded to respective adjacent fourth row bond pads 538 at different wire bond site locations 542 along their respective longitudinal axes L2.

Each of the first row bond pads 516 overlay two other adjacent circuit external interface cells 510 that sandwich the respective directly underlying interface cell 510. Additionally, each of the second row bond pads 520 overlay two adjacent circuit external interface cells 510 that sandwich the respective directly underlying interface cell 510. Similarly, the third and fourth row bond pads 532, 538 overlay two adjacent circuit external interface cells 528 that sandwich the respective directly underlying interface cell 528.

As will be apparent to a person skilled in the art, an encapsulation material (not shown) typically encapsulates the semiconductor die 504, bond wires 546, die flag 506 and external connector wire bond locations 502.

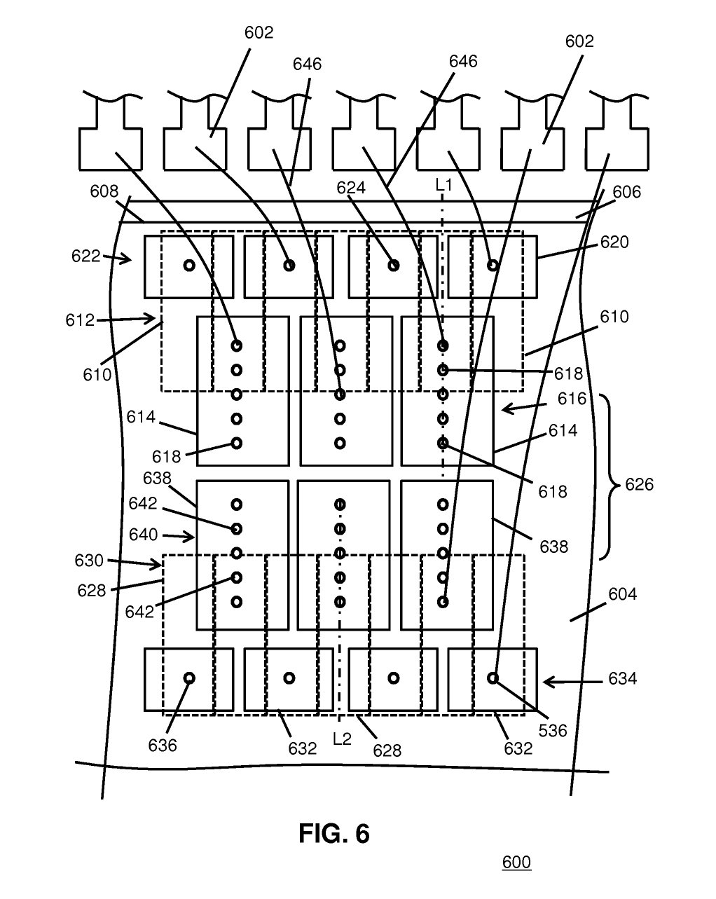

FIG. 6 is a partial plan view of a semiconductor die package 600 according to a fifth embodiment of the present invention. The semiconductor die package 600 includes external connector wire bond locations 602 associated with respective external connectors of the package 600, and a semiconductor die 604 that in this embodiment is mounted on a die flag 606. In this embodiment, the external connector wire bond locations 602 are bond pads at the end of lead fingers as will be apparent to a person skilled in the art.

The semiconductor die 604 has respective edges, such as edge 608, proximal to the external connector wire bond locations 602. The semiconductor die 604 includes a plurality of elongate adjacent external interface cells 610 (indicated in phantom) forming an interface cell row 612. As will be apparent to a person skilled in the art, each of the external interface cells 610 provides an external interface for a circuit node of the semiconductor die 604.

The semiconductor die 604 also includes a plurality of first row bond pads 614 that form a first row of spaced first bond pads 616. Each of the first row bond pads 614 is electrically connected to a directly underlying interface cell 610 of the interface cell row 612. Each of the first row bond pads 614 has a longitudinal axis L1 aligned with a lengthwise axis of their respective directly underlying interface cell 610. Also, each of the first row bond pads 614 has a plurality of potential wire bond site locations 618 (indicated by circles) along their respective longitudinal axes L1.

There is also a plurality of second row bond pads 620 that form a second row of spaced second bond pads 622 and each of the second row bond pads 620 is electrically connected to a directly underlying interface cell 610 of the interface cell row 612. In this embodiment, the second row bond pads 620 each have a single bond site location 624 (indicated by a circle).

Each of the first row bond pads 614 are rectangular and extend to a non-overlying region 626 of the interface cell row 612. In this embodiment, the interface cell row 612 is an outer interface cell row proximal to the proximal edge 608 of the die 604, and the outer interface cell row is located between the proximal edge 608 and the non-overlying region 626. There is also a plurality of inner adjacent external interface cells 628 forming an inner interface cell row 630. Each of the inner external interface cells 628 provides an external interface for a circuit node of the die 604. The semiconductor die package 600 further includes a plurality of third row bond pads 632 that form a third row of spaced third bond pads 634 electrically connected to a directly underlying interface cell 628 of the inner interface cell row 630. In this embodiment, the third row bond pads 632 each have a single bond site location 636 (indicated by a circle).

The semiconductor die 604 also has a plurality of fourth row bond pads 638 forming a fourth row of spaced fourth bond pads 640 that are electrically connected to a directly underlying interface cell 628 of the inner interface cell row 630. The fourth row bond pads 638 have a longitudinal axis L2 aligned with a lengthwise axis of their respective overlaid interface cell 628 and in this embodiment the longitudinal axes L1 and L2 are co-axial. Each of the fourth row bond pads 638 have a plurality of potential wire bond site locations 642 along their respective longitudinal axes L2. Further, each of the fourth row bond pads 638 are rectangular and extend to the non-overlying region 626.

The semiconductor die package 600 also has bond wires 646 that are bonded (welded) to selectively electrically couple each of the bond pads 614, 620, 632, 638 to one of the external connector wire bond locations 602. Further, at least two bond wires 646 are bonded to respective adjacent first row bond pads 614 at different wire bond site locations 618 along their respective longitudinal axes L1. Similarly, at least two bond wires 646 are bonded to respective adjacent fourth row bond pads 668 at different wire bond site locations 642 along their respective longitudinal axes L2.

Each of the first row bond pads 616 overlay two other adjacent circuit external interface cells 610 that sandwich the respective directly underlying interface cell 610. Additionally, each of the second row bond pads 620 overlay two adjacent circuit external interface cells 610 that sandwich the respective directly underlying interface cell 610. Similarly, the third and fourth row bond pads 632, 638 overlay two adjacent circuit external interface cells 628 that sandwich the respective directly underlying interface cell 628.

As will be apparent to a person skilled in the art, an encapsulation material (not shown) typically encapsulates the semiconductor die 604, bond wires 646, die flag 606 and external connector wire bond locations 602.

Advantageously, the present invention allows for flexibility in selecting various bond site locations on certain bond pads of a semiconductor die. This flexibility of bond site selection at least alleviates the need for an increased footprint size of the die and overall package size. This is because, for a given size die, the present invention allows a bond site location to be chosen which improves the possibility of meeting the requirements of: maximum and minimum allowable bond wire height; minimum bond site spacing; and maximum bend angle of each bond wire. Further, the respective runners 438 selectively coupling the overlaid second and third row bond pads 420, 432 reduces the required number of bond wires. Similarly, the overlaying of the first row bond pads 414, interface cells 410, 428, provides for selectively coupling the interface cells 410, 428 together. This again reduces the required number of bond wires.

The description of the preferred embodiments of the present invention has been presented for purposes of illustration and description, but is not intended to be exhaustive or to limit the invention to the forms disclosed. It should also be noted that the circles indicating bond site locations are not actually marked on the bond pads, these circles are depicted purely to indicate some of the actual or potential available bond sites. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A semiconductor die, comprising:
a plurality of elongate adjacent external interface cells forming an interface cell row, wherein each of the external interface cells provides an external interface for a circuit node of the die; and
a plurality of bond pads, each of the bond pads electrically connected to a directly underlying interface cell of the interface cell row, each of the bond pads having a longitudinal axis aligned with a lengthwise axis of the respective directly underlying interface cell, and wherein each of the bond pads has a plurality of potential wire bond site locations along the respective longitudinal axis thereof.

2. The semiconductor die of claim 1, wherein each of the bond pads are rectangular.

3. The semiconductor die of claim 1, wherein each of the bond pads extends to a non-overlying region of the interface cell row.

4. The semiconductor die of claim 3, wherein the bond pads comprise a plurality of first row bond pads that form a first row of spaced first bond pads, and a plurality of second row bond pads that form a second row of spaced second bond pads, wherein each of the second row bond pads is electrically connected to a directly underlying interface cell of the interface cell row.

5. The semiconductor die of claim 4, wherein each of the first row bond pads overlay two other of the adjacent circuit external interface cells that sandwich the respective directly underlying interface cell therebetween.

6. The semiconductor die of claim 5, wherein each of the second row bond pads overlay two said adjacent circuit external interface cells that sandwich the respective directly underlying interface cell therebetween.

7. The semiconductor die of claim 6, wherein the interface cell row is an outer interface cell row proximal to a proximal edge of the die, and wherein the outer interface cell row is located between the proximal edge and the non-overlying region.

8. The semiconductor die of claim 7, further comprising:
a plurality of inner adjacent external interface cells forming an inner interface cell row, each of the inner external interface cells providing an external interface for a circuit node of the die; and
a plurality of third row bond pads forming a third row of spaced third bond pads electrically connected to a directly underlying interface cell of the inner interface cell row.

9. The semiconductor die of claim 8, wherein the third row bond pads are directly selectively electrically connected to one of the respective spaced second bond pads.

10. The semiconductor die of claim 8, further including a plurality of fourth row bond pads forming a fourth row of spaced fourth bond pads that are electrically connected to a directly underlying interface cell of the inner interface cell row, and wherein the fourth row bond pads have a longitudinal axis aligned with a lengthwise axis of their respective overlaid interface cell, and each of the fourth row bond pads has a plurality of potential wire bond site locations along the respective longitudinal axes.

11. The semiconductor die of claim 10, wherein the fourth row bond pads are rectangular.

12. The semiconductor die of claim 10, wherein each of the fourth row bond pads extend to the non-overlying region.

13. The semiconductor die of claim 8, wherein each of the first row bond pads extends to overlay a respective one of the external interface cells of the inner interface cell row.

14. A semiconductor die package, comprising:
external connector wire bond locations associated with respective external connectors of the package;
a semiconductor die that has respective edges proximal to the external connector wire bond locations, and wherein the semiconductor die includes:
a plurality of elongate adjacent external interface cells forming an interface cell row, each of the external interface cells providing an external interface for a circuit node of the die,
a plurality of bond pads, each of the bond pads being electrically connected to a directly underlying interface cell of the interface cell row, wherein each of the bond pads has a longitudinal axis aligned with a lengthwise axis of a respective one of the directly underlying interface cells, and wherein each of the bond pads has a plurality of potential wire bond site locations along the longitudinal axis thereof; and
bond wires selectively electrically coupling each of the bond pads to one of the external connector wire bond locations, wherein at least two of the bond wires are bonded to a respective one of the bond pads at different wire bond site locations along the longitudinal axe thereof.

15. The semiconductor die package of claim 14, wherein the bond pads are rectangular.

16. The semiconductor die package of claim 14, wherein each of the bond pads extends to a non-overlying region of the interface cell row.

17. The semiconductor die package of claim 14, wherein the bond pads comprise a plurality of first row bond pads that form a first row of spaced first bond pads, and a plurality of second row bond pads that form a second row of spaced second bond pads, wherein each of the second row bond pads is electrically connected to a directly underlying interface cell of the interface cell row

18. The semiconductor die package of claim 17, wherein the interface cell row is an outer interface cell row proximal to a proximal edge of the die, and wherein the outer interface cell row is located between the proximal edge and the non-overlying region.

19. The semiconductor die package of claim 18, further comprising:
a plurality of inner adjacent external interface cells forming an inner interface cell row, each of the inner external interface cells providing an external interface for a circuit node of the die; and
a plurality of third row bond pads forming a third row of spaced third bond pads electrically connected to a directly underlying interface cell of the inner interface cell row.

20. The semiconductor die package of claim 19, further including a plurality of fourth row bond pads forming a fourth row of spaced fourth bond pads that are electrically connected to a directly underlying interface cell of the inner interface cell row, and wherein the fourth row bond pads have a longitudinal axis aligned with a lengthwise axis of their respective said overlaid interface cell, and each of the fourth row bond pads have a plurality of potential wire bond site locations along their respective longitudinal axes.
